(19) United States
(12) Patent Application Publication
(10) Pub. No.: US 2013/0199591 A1
(43) Pub. Date: Aug. 8, 2013

(54) Arrangement for Generating Electricity with Thermoplastic Generators and Solar Energy Collector Means

(71) Applicants: Ahsan Khan, Hawarden (GB); Philip Parkin, Rotherham (GB)

(72) Inventors: Ahsan Khan, Hawarden (GB); Philip Parkin, Rotherham (GB)

(73) Assignee: TATA STEEL UK LIMITED, London (GB)

(21) Appl. No.: 13/637,964

(22) PCT Filed: Mar. 30, 2011
(86) PCT No.: PCT/EP2011/001585

§ 371 Date: Dec. 5, 2012

(30) Foreign Application Priority Data
Mar. 30, 2010 (EP) 10003432.1

(51) Int. Cl. H01L 35/30

(52) U.S. Cl. CPC H01L 35/30
USPC 136/206

(57) ABSTRACT

An arrangement for generating electricity including thermoelectric generators, the generators converting a heat difference between a first and a second surface of a generator in electricity, elements to provide a heated first medium to the first surfaces of the one or more thermoelectric generators and elements to provide a second medium with a temperature lower than that of the first medium to the second surfaces of the one or more thermoelectric generators. The first medium is heated by solar energy collector elements, which solar energy collector elements transfer collected solar energy to air passing through the solar energy collector elements. The first medium is a working fluid or the heated air itself. The second medium is a working fluid or ambient air with a lower temperature than the first medium.

The invention relates to an arrangement for generating electricity comprising one or more thermoelectric generators, said generators converting a heat difference between a first and a second surface of a generator in electricity, wherein heat captured by solar energy collector means is used to heat one surface of the thermoelectric generators.

These thermoelectric generators (TEG) are well known and are mainly used in applications where it is not very well possible to use larger thermal to electric conversion systems. For instance in the automotive industry thermoelectric generators are applied to recover waste heat from the combustion engine and provide in that way at least part of a car's electric power needs.

Solar energy collector means are known in the art, see for instance US4934338, and are used to generate heated air for space heating or other indoor heating purposes like drying processes. In all kinds of buildings these collector panels can be integrated in the façade or roof so that large areas will be available to collect and transfer solar energy into heated air. The air-outlet duct of the solar energy collector means is connected to the interior of the building to introduce the heated air into the building. These solar energy collector means are also known as “transpired solar collector”. In this way a reduction in the costs for other means for heating can be achieved. However, not all heated air generated by the solar energy collector means is or can be used for indoor heating, for instance because to much heated air is generated or not all heated air can be directed to the interior of the building.

From DE 102008009979 a system is known in which in a closed solar collector heated air is pumped round with electrical means along a first surface of a thermoelectric generator while the second surface of the thermoelectric generator is in contact with ambient air.

It is an objective of the present invention to provide an arrangement to generate electricity using the surplus of heat generated by solar energy collector means, more in particular by using a transpired solar collector.

It is a further objective of the invention to provide an arrangement that is suitable to generate electricity over a large range of temperature difference between both surfaces of the thermoelectric generators.

It is still a further objective of the invention to provide an arrangement to generate electricity that is of a simple and reliable construction.

It is still a further objective of the invention to provide an arrangement to generate electricity that is easily accessible for maintenance.

According to a first aspect of the invention one or more of the above objectives are realized by providing an arrangement for generating electricity comprising one or more thermoelectric generators, said generators converting a heat difference between a first and a second surface of a generator into electricity, means to provide a heated first medium to the first surfaces of the one or more thermoelectric generators and means to provide a second medium with a temperature lower than that of the first medium to the second surfaces of the one or more thermoelectric generators, wherein the first medium is air heated by means of solar energy collector means, which solar energy collector means define an at least partly enclosed space provided with one or more solar energy absorbing panels, air-inlet openings connecting the outside with the at least partly enclosed space and an air-outlet duct connected to the at least partly enclosed space, and wherein the second medium is ambient air, in which the first surfaces of the one or more thermoelectric generators are in thermal contact with the air inside the at least partly enclosed space and in which the second surfaces of the one or more thermoelectric generators are in thermal contact with ambient air.

The solar energy collector means define an at least partly enclosed space provided with one or more solar energy absorbing panels, air-inlet openings in the panels connecting the outside with the at least partly enclosed space and an air-outlet duct connected to the at least partly enclosed space. The air-inlet openings may connect to one or more air channels within the collector panel to guide the air along the solar energy collecting side of the panel and to control the air flow within the at least partly enclosed space. The air-outlet duct is to guide the heated outside air into a building for heating purposes. These panels can be mounted against a side wall or an inclined side of a building or other structure and may form the at least partly enclosed space together with said side wall or inclined side.

According to the invention the air heated by the solar energy collecting means is guided along the thermoelectric generators which is a simple and effective means of transferring heat to the first surfaces of the thermoelectric generators. According to a further aspect of the invention the one or more thermoelectric generators are positioned upstream of the air-outlet duct connected to the at least partly enclosed space. At such a location there is sufficient or more than sufficient air flow to transfer heat to the first surfaces of the thermoelectric generators.

The air-outlet ducts guiding the heated air into for instance an air heating system of a building are often positioned at a distance from the top of the at least partly enclosed space. The reason being that the heated air is taken out the at least partly enclosed space through the air-outlet ducts by means of a fan inside the building and to prevent that ambient air is drawn in through the top of the partly enclosed space the air-outlet ducts are positioned at a distance from the top.

It is also possible to place the thermoelectric generators away from these air-outlets or in between air-outlet ducts. In such an embodiment the thermoelectric generators will be positioned downstream of these air-outlet ducts, which will mean a position above the air-outlet ducts, and seen horizontally in between air-outlet ducts. With such a configuration a further opening in the enclosed space may be provided which connects the enclosed space with the outside, in order to generate an increased flow of heated air over the first surfaces of the thermoelectric generators to transfer sufficient heat to said first surfaces. Although in that way heated air is finally fed back to the outside and lost for heating purposes of the interior of a building, this will not be a problem with most of these transpired solar collectors, since because of large surface areas of such collectors and a limited number of air-outlet ducts to the inside of a building there is often more than enough capacity to use a part of the heated air to generate electricity.

Moreover, with many of these transpired solar collectors the top of the partly enclosed space is provided with outlet openings to be able to let excess heated air escape from the at least partly enclosed space. If so these outlet opening may be used to have sufficient heated air flow over the first surfaces of the one or more thermoelectric generators.

Since the thermoelectric generators have only a low voltage output preferably a number of thermoelectric generators are connected in series to get sufficient voltage output. For that reason the thermoelectric generators are preferably positioned together in an array.

In order to realize an effective transfer of heat the first and/or second surfaces of the one or more thermoelectric generators are connected to a respective heat exchanger. One of these heat exchangers may be positioned directly on the first or second surfaces of the thermoelectric generators.

According to a further aspect of the invention it is provided that the first surfaces of the one or more thermoelectric generators are connected to a heat exchanger which is positioned in the flow of the heated air of the partly enclosed space of the solar energy collector means, the second surfaces of the one or more thermoelectric generators are connected to a heat exchanger positioned outside the partly enclosed space of the solar energy collector means in an air duct, the air duct having an inlet and an outlet for ambient air.

It will be dependent on the construction of the transpired solar collector and the air duct for ambient air whether or not the thermoelectric generators can be mounted such that the first and/or second surfaces of the thermoelectric generators can be put in direct thermal contact with respective heated air and ambient air. If the contact is poor or to improve thermal contact heat exchangers are provided for instance in the form of fins that make sufficient thermal contact with respective heated air and/or ambient air.

With existing transpired solar collector configurations, it will not very well possible to mount the thermoelectric generators such that the first surfaces of the thermoelectric generators are inside the at least partly enclosed space and the second surfaces outside said enclosed space and in the air duct. In this case the options are to position the thermoelectric generators inside or outside the at least partly enclosed space and thermally connect one of the respective first and second surfaces of the thermoelectric generators with either the air duct for ambient air or the at least partly enclosed space.

According to a further aspect of the invention it is provided that the first and/or second surfaces of the one or more thermoelectric generators are respectively connected by means of one or more heat pipes to the respective heat exchangers. This allows to thermally connect the first and second surfaces of the one or more thermoelectric generators to respectively the heated air in the at least partly enclosed space and the ambient air in the air duct for ambient air also in constructions were that would otherwise not be possible. Heat pipes are well known and are used in many applications. A typical heat pipe consists of a sealed pipe or tube made of a material with high thermal conductivity at the hot and cold ends. All air is removed from the pipe and only partly replaced by a working fluid that matches the operating temperature range of the arrangement. Because of the partial vacuum that is near or below the vapour pressure of the working fluid, part of the fluid will be in the liquid phase and part will be in the gas phase. The gas is condensed to a liquid at the cold end after which the liquid returns by means of capillary action or gravity action to the hot end where the liquid evaporates again.

With the heat pipes a very effective heat transport can be realized from heat exchanger to the first and/or second surfaces of the one or more thermoelectric generators. In order to get the heat to or from the said surfaces the first and/or second surfaces of the one or more thermoelectric generators are attached to a plate, which plate is connected to the one or more heat pipes to the respective heat exchangers. The plate is a thermally conductive plate spreading the heat over or taking the heat from the surfaces of the thermoelectric generators and the heat pipes are preferably accommodated in the plate for optimal heat transfer between the heat pipes and the plates.

With this embodiment the heat exchange from the heated air and the first surfaces of the thermoelectric generators takes place directly in the partly enclosed space of the solar energy collector means while the second surfaces are kept at a lower temperature by means of the heat pipes and a heat exchanger outside the at least partly enclosed space.

According to a further aspect of the invention an open connection is provided between the partly enclosed space and the outlet of the air duct for ambient air at a distance downstream of the heat exchangers.

The open connection between the at least partly enclosed space and the air duct has the advantage that the heated air passing the open connection creates an lower pressure with respect to the pressure in the at least partly enclosed space by which the ambient air in the air duct will get entrained by the flow of the heated air in the at least partly enclosed space. The flow of the ambient air is increased through entrainment thereof by the heated air to realize an increased cooling of the second surfaces of the thermoelectric generators.

It may further be provided that a wind driven ventilation device is provided on the air outlet of the air duct. These passive ventilating devices may have spherical or vertical vanes which further aid wind driven ventilation. Such devices are also known as wind turbine ventilators.

According to a further elaboration it may also be provided that two different air outlets are provided, one outlet for the air duct for ambient air and a separate outlet opening for the heated air in the partially enclosed space. One of these outlets or both of these outlets may be provided with a wind driven ventilation device.

According to a further aspect of the invention the second surfaces of the one or more thermoelectric generators are connected to a plate, which plate is connected by means of one or more heat pipes to the heat exchanger in the air duct.

According to a further aspect of the invention it is provided that the heat exchangers are provided with fins running in the direction of the air flow, therewith realizing an optimal heat exchange between heat exchanger and passing heated air.

According to a further aspect of the invention it is provided that the fins of the heat exchanger in the air duct have a curved surface. Alternatively the fins may have a plane surface orientated at an angle in the duct for ambient air or have angled surfaces. With the construction of the air duct it will often be inevitable that inlet and outlet of the air duct are at an angle to each other. This necessitates a curved or angled surface of the fins or fins with a plane surface positioned at an angle in the duct for ambient air to have the ambient air at the opening between the air duct and the at least partly enclosed space flow in about the same direction as the heated air in the at least partly enclosed space.

According to a further aspect of the invention separate groups of one or more thermoelectric generators are positioned at least partly inside the partly enclosed space of the solar energy collector means. Depending on the size of the solar energy collector means and the number of air-outlet ducts connected to the at least partly enclosed space it will be possible to position more than one group of thermoelectric generators. The separate output terminals of these groups of thermoelectric generators can be coupled.

The invention will further be elucidated on hand of the examples given in the drawings, wherein:

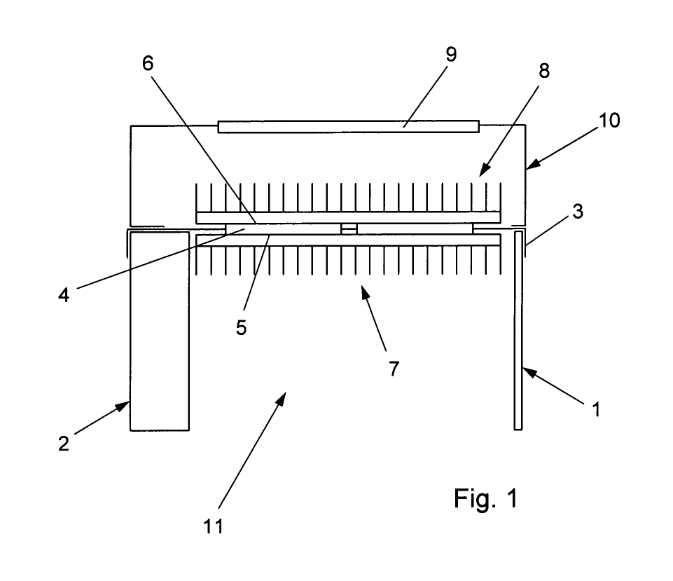

FIG. 1 shows schematically a sectional view of a first embodiment of the solar energy collector means and thermoelectric generators;

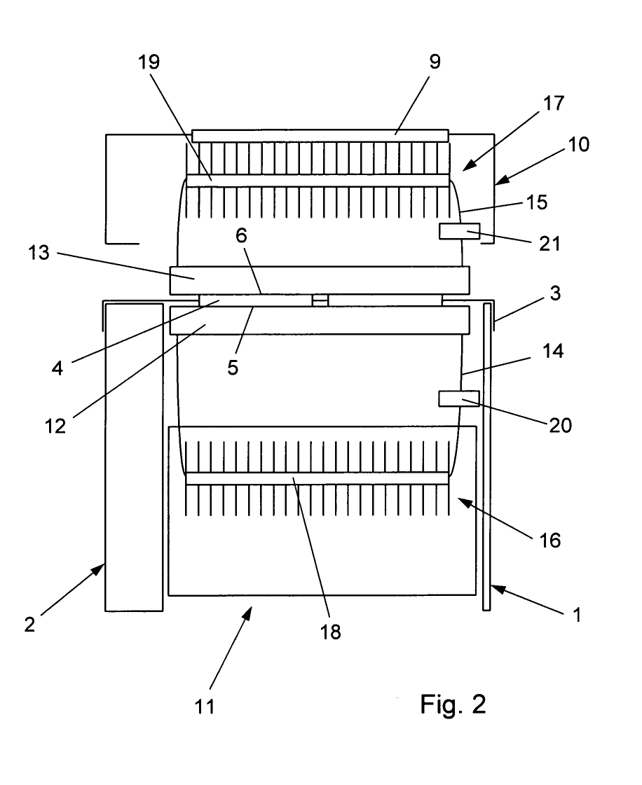

FIG. 2 shows schematically a sectional view of a second embodiment of the solar energy collector means and thermoelectric generators;

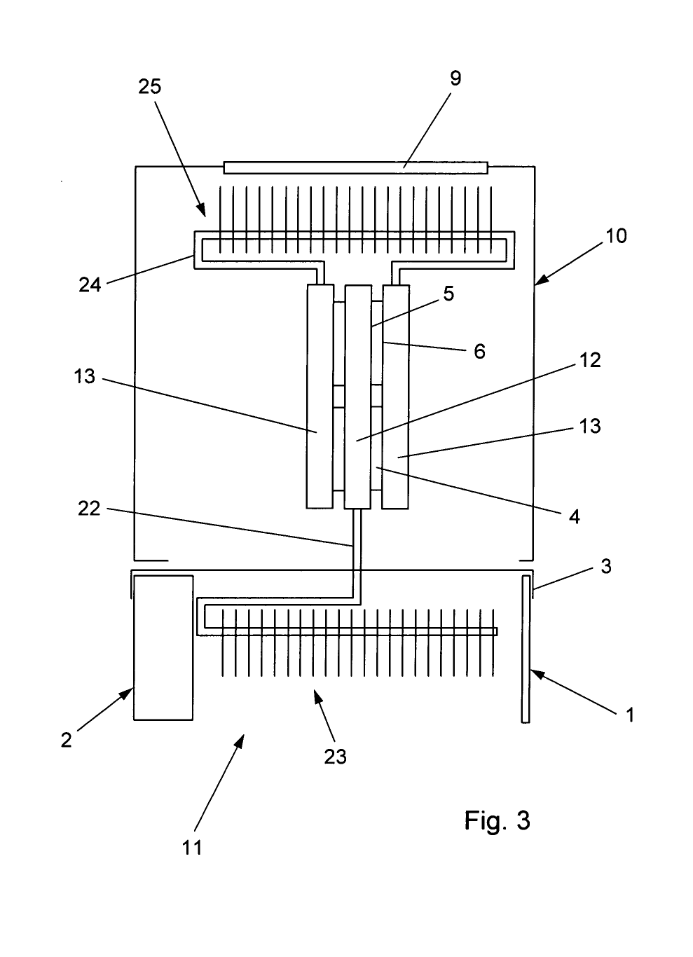

FIG. 3 shows schematically a sectional view of a third embodiment of the solar energy collector means and thermoelectric generators, and

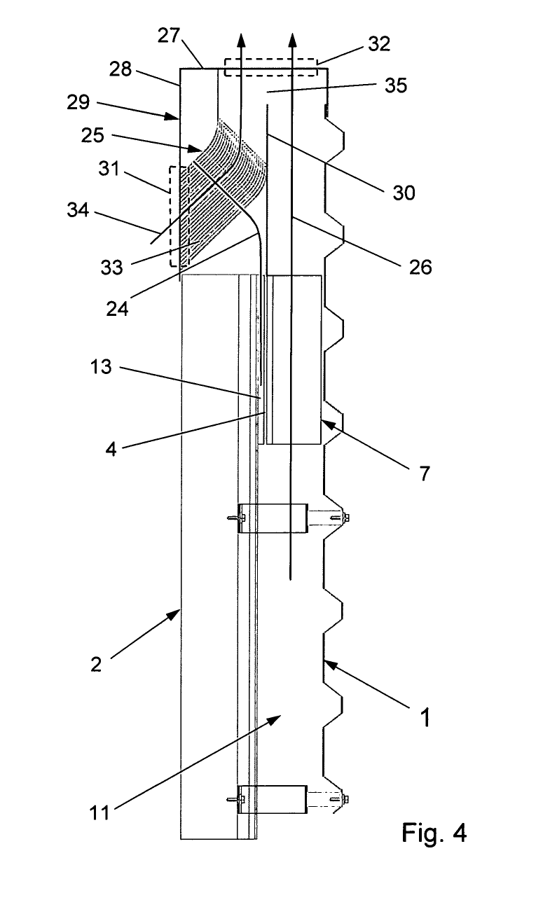

FIG. 4 shows schematically a perspective view of a fourth embodiment of the solar energy collector means and thermoelectric generators.

The embodiment according to FIG. 1 has solar energy collector means comprising an outer panel 1 and a wall structure 2 of a building and a top cover 3 which together form the at least partly enclosed space. Although not indicated in the drawing the outer panel is provided with air-inlet openings connecting the outside environment with the at least partly enclosed space 11. The air-inlet openings usually connect to one or more air channels within the collector panel to guide the air along the solar energy collecting side of the panel and to control the air flow within the panel. The heated air is drawn from the at least partly enclosed space into the building through and an air-outlet duct which is at a level below the section shown in the drawing.

In top cover 3 thermoelectric generators 4 are mounted with the first surfaces 5 of the thermoelectric generators facing the inside of the at least partly enclosed space 11 and with the second surfaces 6 facing in the opposite direction. The first and second surfaces 5,6 are respectively provided with heat exchangers 7,8. A protective housing 10 is provided covering the second surfaces 6 and heat exchanger 8 from direct exposure to the outdoor climate. The first surfaces 5 of the thermoelectric generators 4 are heated by means of the heat extracted from the heated air ascending in the at least partly enclosed space 11. The second surfaces 6 are cooled by means of ambient air passing through heat exchanger 8. To get sufficient ambient air pass through heat exchanger 8 a fan 9 is provided. The ambient air enters the protective housing 10 through air inlets not indicated in the drawing.

The numbering used in FIG. 1 is maintained for the same or similar parts in the other embodiments shown in the other figures.

In the embodiment according to FIG. 2 the thermoelectric generators 4 are again positioned in top cover 3 of the at least partly enclosed space 11. Directly against the first and second surfaces 5,6 of the thermoelectric generators 4 thermally conductive plates 12,13 are respectively attached. In the plates 12,13 one or more channels or similar provisions have been provided for a working fluid to pass through the respective plates 12,13. The working fluid is passed through pipes 14,15 to the respective heat exchangers 16,17 which in the same manner as plates 12,13 are provided with one or more channels to pass the working fluid through a central part 18,19 of the heat exchangers 16,17. In order to keep the working fluid go round fluid pumps 20,21 are provided.

In the embodiments shown in FIG. 1 and FIG. 2 the thermoelectric generators 4 are positioned directly in a plate that partitions the at least partly enclosed space 11 with the outside. However, this will not in all cases be possible or be the most feasible construction.

In the embodiment shown in FIG. 3 the thermoelectric generators 4 are placed completely outside the at least partly enclosed space 11. The thermoelectric generators 4 are placed in two rows with their first surfaces 5 against a thermally conductive plate 12 and their second surfaces 6 against thermally conductive plates 13. One or more heat pipes 22 are accommodated in plate 12 and pass through top cover 3 to heat exchanger 23 positioned in the at least partly enclosed space 11. The heat pipes 22 are connected with the cold end to plate 12 and with the hot end with heat exchanger 23. The heat pipes are preferably positioned such that the working fluid in the heat pipes after condensing at the cold end return to the hot end by gravitation.

The second surfaces 6 of the thermoelectric generators 4 are connected to plates 13 which in a like manner are provided with heat pipes 24 connected to heat exchanger 25. In this embodiment also a fan 9 is provided to get sufficient ambient air pass heat exchanger 25.

In the embodiment according to FIG. 4 the thermoelectric generators 4 are oriented differently than in the previous embodiments, that is with the first surfaces 5 of thermoelectric generators 4 in a plane parallel to the general flow direction of the heated air in the at least partly enclosed space 11, indicated with arrow 26. The first surfaces 5 are in direct contact with heat exchanger 7. Heat exchanger 7 is provided with fins parallel to the flow direction of the heated air as indicated with arrow 26. The fins preferably extend over most or complete width of the at least partly enclosed space. With this embodiment an optimal heat exchange between the heated air resulting from the solar energy collector means and the first surfaces 5 of thermoelectric generators 4 can be realized.

In this embodiment panel 1 is extended over a distance above the top of wall structure 2 and forms together with top part 27 and side part 28 a housing 29 standing out above wall structure 2. A separator plate 30 separates the space of housing 29 in two parts, wherein the part on the left side of separator plate 30 in the drawing forms a duct for ambient air and houses a heat exchanger 25. Heat exchanger 25 is connected to plate 13 by means of heat pipes 24 and the second surfaces 6 of thermoelectric generators 4 are connected to plate 13. The orientation of the heat pipes 24 with respect to the orientation of fins 33 of heat exchanger 25 is indicated schematically in the drawing. It will be understood that for good thermal contact that the end part of a heat pipe may be in contact with the surfaces of a fin of the heat exchanger.

The side part 28 is provided with air inlets generally indicated with dotted line 31 for ambient air. The top part 27 is provided with air outlets generally indicated with dotted line 32, which are outlets for both ambient air that has passed heat exchanger 25 and heated air that has passed heat exchanger 7.

Heat exchanger 25 is provided with curved fins 33 that guide the ambient air from the air inlets 31 to air outlets 33. The general air flow is indicated with arrow 34 that at the end of separator plate 30 is in generally the same direction as the flow of the heated air indicated with arrow 26.

Ambient air will in most cases enter through air inlets 31 as a result of the wind. With the configuration according to FIG. 4 the separator plate 30 leaves an opening between the end of separator plate 30 and top part 27, resulting in an opening 35 between the part for cold ambient air and the at least partly enclosed space with heated air. The flow of the heated air past separator plate 30 will result in a reduced pressure at the other side of separator plate 30 and as a result the ambient air will get entrained by the heated air passing opening 35. This will mean an improved flow of ambient air along the fins of heat exchanger 25 and together with an optimal flow of the heated air along the fins of heat exchangers 7 a sufficient temperature difference between the first and second surfaces 5,6 of the thermoelectric generators 4 can be realized.

The entraining of the ambient air by the heated air flowing past opening 35 can further be increased by increasing the flow velocity of the heated air. To that end separator plate 30 is curved or has as seen in cross-section a flat side and a curved side with the convex side of the curved separator plate pointing in the direction of panel 1.

1. An arrangement for generating electricity comprising:
one or more thermoelectric generators, said generators for converting a heat difference between a first surface and a second surface of a generator into electricity,
means to provide a heated first medium to the respective one or more first surfaces of the one or more thermoelectric generators and
means to provide a second medium with a temperature lower than that of the first medium to the respective one or more second surfaces of the one or more thermoelectric generators,
solar energy collector means,
wherein the heated first medium is air heated by the solar energy collector means, which solar energy collector means define an at least partly enclosed space provided with one or more solar energy absorbing panels, air-inlet openings connecting the outside with the at least partly enclosed space and an air-outlet duct connected to the at least partly enclosed space, and wherein the second medium is ambient air, in which the respective one or more first surfaces of the one or more thermoelectric generators are in thermal contact with the air inside the at least partly enclosed space and in which the respective one or more second surfaces of the one or more thermoelectric generators are in thermal contact with the ambient air.

2. The arrangement according to claim 1, wherein the first surfaces of the one or more thermoelectric generators are connected to a heat exchanger positioned in the flow of the heated air of the partly enclosed space of the solar energy collector means, the respective one or more second surfaces of the one or more thermoelectric generators are connected to a heat exchanger positioned outside the partly enclosed space of the solar energy collector means in an air duct, the air duct having an inlet and an outlet for ambient air.

3. The arrangement according to claim 2, wherein an open connection is provided between the partly enclosed space and the outlet of the air duct for ambient air at a distance downstream of the heat exchangers.

4. The arrangement according to claim 2, wherein a wind driven ventilation device is provided on the air outlet of the air duct.

5. The arrangement according to claim 3, wherein the respective one or more second surfaces of the one or more thermoelectric generators are connected to a plate, which plate is connected by one or more heat pipes to the heat exchanger in the air duct.

6. The arrangement according to claim 1, wherein the heat exchangers have fins running in the direction of the air flow.

7. The arrangement according claim 6, wherein the fins of the heat exchanger in the air duct have a curved surface.

8. The arrangement according to claim 1, wherein the one or more thermoelectric generators are positioned upstream of the air-outlet duct connected to the at least partly enclosed space.

9. The arrangement according to claim 1, wherein separate groups of one or more thermoelectric generators are positioned at least partly inside the partly enclosed space of the solar energy collector means.

10. The arrangement of claim 1, wherein the means to provide the second medium with the temperature lower than that of the first medium to the respective one or more second surfaces of the one or more thermoelectric generators comprises a fan.
